(19) United States
(12) Patent Application Publication
(10) Pub. No.: US 2016/0247815 A1
(43) Pub. Date: Aug. 25, 2016

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventor: Tomoya OORI, Kuwana (JP)

(73) Assignee: Kabushiki Kaisha Toshiba, Minato-ku (JP)

(21) Appl. No.: 14/731,877

(22) Filed: Jun. 5, 2015

Related U.S. Application Data
(60) Provisional application No. 62/118,238, filed on Feb. 19, 2015.

(51) Int. Cl. H01L 27/115; H01L 21/768; H01L 21/3213; H01L 21/027; H01L 21/311

(52) U.S. Cl. CPC H01L 27/11582; H01L 21/0274; H01L 21/31144; H01L 21/32139; H01L 21/76805; H01L 21/76816

(57) ABSTRACT

According to one embodiment, it includes a stacked body formed such that a first layer and a second layer, which are made of materials different from each other, are alternately stacked, and one of layers of the first layer or one of layers of the second layer is replaced with a third layer that does not transmit light of a wavelength λ, and an opening that penetrates the stacked body in a stack direction and has a diameter or width smaller than the wavelength λ.

### CROSS-REFERENCE TO RELATED APPLICATIONS

This application is based upon and claims the benefit of priority from U.S. Provisional Application No. 62/118,238, filed on Feb. 19, 2015; the entire contents of which are incorporated herein by reference.

### FIELD

Embodiments described herein relate generally to a semiconductor device and a manufacturing method of a semiconductor device.

### BACKGROUND

Along with an increase in the integration degree of semiconductor devices, the aspect ratio of openings has become higher. As the aspect ratio of openings is higher, the openings become more difficult to form in a vertical state, and thereby generate a bowing shape in some cases.

### Disclosure of Invention

### BRIEF DESCRIPTION OF THE DRAWINGS

FIGS. 1A to 1E illustrate sectional views showing a method of forming an opening of a semiconductor device according to a first embodiment;

FIGS. 2A to 2D illustrate sectional views showing the method of forming an opening of a semiconductor device according to the first embodiment;

FIGS. 3A to 3E illustrate sectional views showing a method of forming an opening of a semiconductor device according to a second embodiment;

FIGS. 4A to 4D illustrate sectional views showing the method of forming an opening of a semiconductor device according to the second embodiment;

FIGS. 5A to 5F illustrate sectional views showing a method of manufacturing a memory cell array of a nonvolatile semiconductor memory device according to a third embodiment;

FIGS. 6A to 6F illustrate sectional views showing a method of manufacturing a memory cell array of a nonvolatile semiconductor memory device according to a fourth embodiment;

FIGS. 7A to 7D illustrate sectional views showing the method of manufacturing a memory cell array of a nonvolatile semiconductor memory device according to the fourth embodiment;

FIGS. 8A to 8D illustrate sectional views showing a method of manufacturing a memory cell array of a nonvolatile semiconductor memory device according to a fifth embodiment;

FIGS. 9A to 9D illustrate sectional views showing the method of manufacturing a memory cell array of a nonvolatile semiconductor memory device according to the fifth embodiment;

FIG. 10 is a perspective view showing a schematic configuration example of a memory cell array of a nonvolatile semiconductor memory device according to a sixth embodiment;

FIG. 11 is a sectional view showing a portion E of FIG. 10 in an enlarged state;

FIG. 12 is a perspective view showing a schematic configuration example of a memory cell array of a nonvolatile semiconductor memory device according to a seventh embodiment; and

FIG. 13 is a sectional view showing a portion E of FIG. 12 in an enlarged state.

### DETAILED DESCRIPTION

In general, according to one embodiment, it includes a stacked body and an opening. The stacked body is formed such that a first layer and a second layer, which are made of materials different from each other, are alternately stacked, and one of layers of the first layer or one of layers of the second layer is replaced with a third layer that does not transmit light of a wavelength λ. The opening penetrates the stacked body in a stack direction and has a diameter or width smaller than the wavelength λ.

Exemplary embodiments of a semiconductor device and a manufacturing method of a semiconductor device will be explained below in detail with reference to the accompanying drawings. In the following description, the semiconductor device is exemplified by a nonvolatile semiconductor memory device. The present invention is not limited to the following embodiments.

### First Embodiment

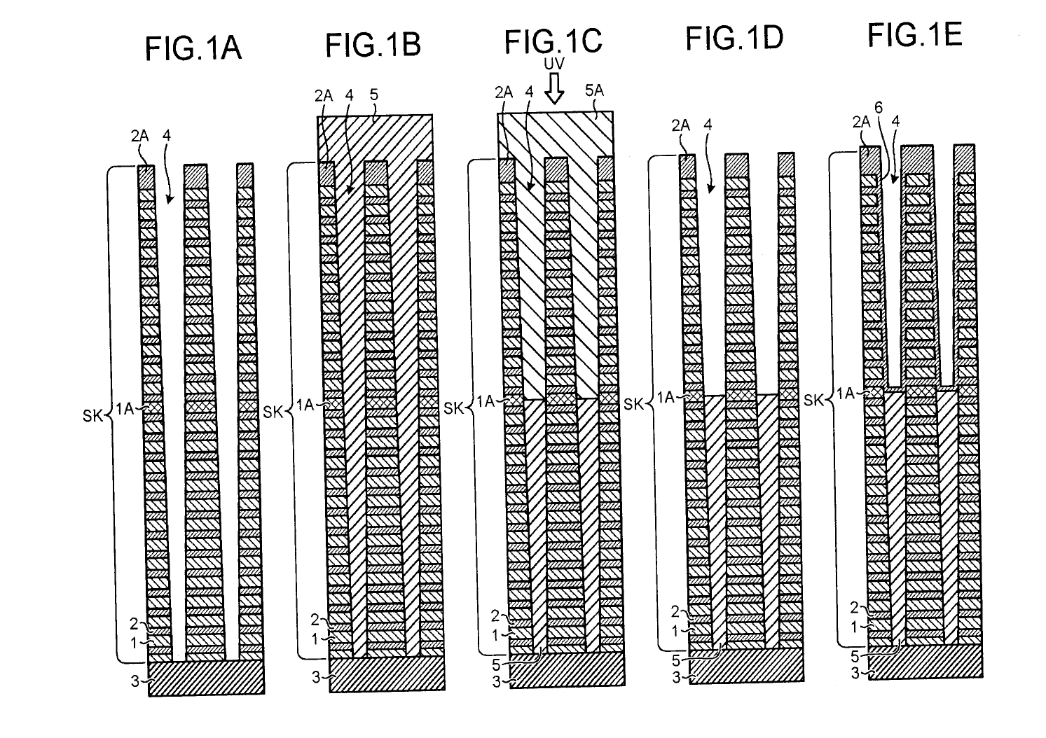

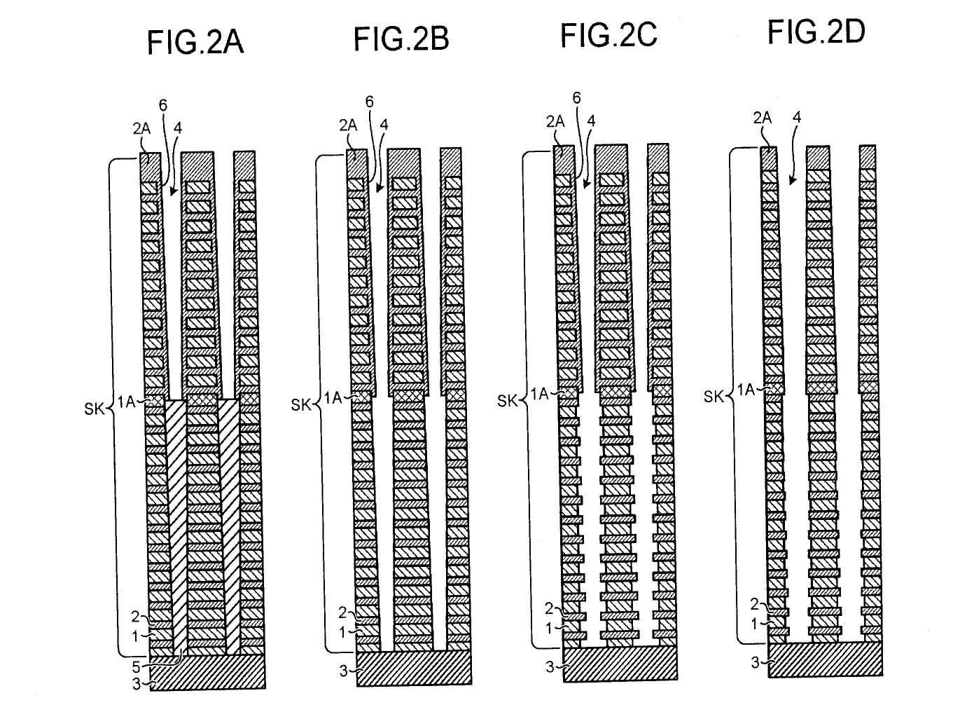

In FIGS. 1A to 1E, and FIGS. 2A to 2D, sectional views show a method of forming an opening of a semiconductor device according to a first embodiment. Here, the configuration shown in FIGS. 1A to 1E, and FIGS. 2A to 2D, is exemplified by a case where a first layer and a second layer are stacked such that 24 layers of each are present.

As shown in FIG. 1A, a stacked body SK is formed on an underlying layer 3 by use of a CVD method or the like, such that the first layer 1 and the second layer 2, which are made of materials different from each other, are alternately stacked, and one of layers of the first layer 1 or one of layers of the second layer 2 is replaced with a third layer 1A, in the stacked body SK. In the example shown in FIG. 1A, the 14th first layer 1 is replaced with the third layer 1A. The 14th first layer 1 may be replaced with the third layer 1A by use of such a method that the first layer 1 and the second layer 2 are alternately stacked each in 13 layers, then the third layer 1A is stacked, and subsequently the second layer 2 and the first layer 1 are alternately stacked each in 11 layers. Further, a cap layer 2A may be stacked on the uppermost layer of the stacked body SK. The cap layer 2A may be made of the same material as that of the second layer 2. Further, the underlying layer 3 may be a semiconductor substrate, may be an insulating body, or may be a wiring layer. The combination of the first layer 1 and the second layer 2 may be formed of a silicon layer doped with an impurity and a silicon oxide film, may be formed of a silicon layer doped with an impurity at a high concentration and a silicon layer doped with an impurity at a low concentration, or may be formed of a silicon nitride film and a silicon oxide film. The third layer 1A may be made of a material that does not transmit exposure light UV of a wavelength λ. The material of the third layer 1A may be polycrystalline silicon, may be a metal-containing film, such as tungsten, tungsten silicide, titanium, or titanium nitride, or may be a carbon film. The one layer film thickness of each of the first layer 1, the second layer 2, and the third layer 1A may be set to 40 nm, for example. The film thickness of the third layer 1A may be set different from the one layer film thickness of each of the first layer 1 and the second layer 2. When the second layer 2 and the cap layer 2A are made of the same material, the cap layer 2A may be used as an interlayer insulating film on the stacked body SK.

Then, patterning is performed to the stacked body SK by use of a photolithography technique and a dry etching technique, so that openings 4 are formed to penetrate the stacked body SK in the stack direction. Here, each opening 4 may be set to have a diameter smaller than the wavelength λ of the exposure light UV. For example, when an i-line (365 nm) is used as the exposure light UV, each opening 4 may be set to have a diameter of 100 nm. At this time, the opening 4 may accept generation of a bowing shape in which the diameter at the middle is enlarged.

Then, as shown in FIG. 1B, a resist film 5 is uniformly formed on the entire surface of the stacked body SK by use of a spin coating method or the like, so that the resist film 5 is embedded in the openings 4. The resist film 5 may have sensitivity to the exposure light UV of the wavelength λ.

Then, as shown in FIG. 1C, the resist film. 5 is uniformly irradiated with the exposure light UV, and the resist film 5 is thereby exposed to light, so that a latent image 5A is formed in the resist film 5. At this time, since the exposure light UV cannot be transmitted through the third layer 1A, the exposure light UV is prevented from reaching the part of the resist film 5 below the third layer 1A. Consequently, the latent image 5A is prevented from being formed in the part of the resist film 5 below the third layer 1A. In this respect, where d1 denotes the thickness of the third layer 1A, k1 denotes the extinction coefficient of the third layer 1A relative to the wavelength λ, Ein denotes the light exposure amount of the resist film 5 with light of the wavelength λ, and Eth denotes the sensitivity of the resist film 5, the following relationship is preferably satisfied:

Ein×exp(−4π·k1·d1/λ)<Eth

Then, as shown in FIG. 1D, development is performed to the resist film 5 including the latent image 5A formed therein. At this time, that part of the resist film 5, in which the latent image 5A is formed, is removed. Here, since the latent image 5A is not formed in the part of the resist film 5 below the third layer 1A, the setback position of the resist film 5 agrees with the position, corresponding to the third layer 1A, and the uniformity in setback amount of the resist film 5 can thereby be improved. For example, if no third layer 1A is provided, the setback amount of the resist film 5 varies among the openings 4 by about 100 nm. On the other hand, when the third layer 1A is provided, the variation among the openings 4 in terms of the setback amount of the resist film 5 can be reduced to about 20 nm.

Then, as shown in FIG. 1E, a protection film 6 is formed on the sidewall of each opening 4 above the third layer 1A by use of a CVD method or the like. The protection film 6 may be made of a material having a smaller etching rate than those of the first layer 1 and the second layer 2. Alternatively, the protection film 6 may be made of the same material as that of the layer having a smaller etching rate of the first layer 1 and the second layer 2. For example, when the first layer 1 is a silicon layer doped with an impurity and the second layer 2 is a silicon oxide film, the protection film 6 may be formed of a silicon nitride film or may be formed of a silicon oxide film. Alternatively, when the first layer 1 is a silicon layer doped with an impurity at a high concentration and the second layer 2 is a silicon layer doped with an impurity at a low concentration, the protection film 6 may be formed of a silicon oxide film.

Then, as shown in FIG. 2A, the protection film 6 is etched back, so that, while the protection film 6 on the sidewall of each opening 4 above the third layer 1A is left, the surface of the resist film 5 in the lower side of the opening 4 is exposed.

Then, as shown in FIG. 28, the part of the resist film 5 in the lower side of the opening 4 is removed by use of an ashing method or the like.

Then, as shown in FIG. 2C, the sidewall of each first layer 1 in the lower side of the opening 4 is set back in the lateral direction by use of an isotropic etching method or the like. This setback amount of the first layer 1 is preferably set such that the diameter of the opening 4 above the third layer 1A agrees with the diameter of the opening 4 below the third layer 1A.

Then, as shown in FIG. 2D, the sidewall of each second layer 2 in the lower side of the opening 4 is set back in the lateral direction by use of an isotropic etching method or the like. This setback amount of the second layer 2 is preferably set such that the diameter of the opening 4 above the third layer 1A agrees with the diameter of the opening 4 below the third layer 1A. Here, when the second layer 2 and the protection film 6 are made of the same material, the protection film 6 can be removed at the same time when the second layers 2 are set back, and so the number of process steps can be reduced.

In this embodiment, one layer of the first layers 1 or second layer 2 is replaced with the third layer 1A, so that, when light of the wavelength λ is incident into each opening 4, the light is prevented from being transmitted below the third layer 1A. Consequently, for the resist film 5 embedded in each opening 4, exposure to light can be stopped at the position corresponding to the third layer 1A, so that the uniformity in setback amount of the resist film 5 embedded in the openings 4 can be improved. As a result, the uniformity in height where the openings 4 are exposed from the protection film 6 is improved, and the uniformity in etching amount to the openings 4 in the lateral direction can be improved, so that the uniformity in width of the openings 4 can thereby be improved.

It should be noted that the opening 4 may have a flat shape. A flat opening 4 may be exemplified by an elliptical hole of a slit. In such a case, the polarization direction of the exposure light UV is preferably set perpendicular to the longitudinal direction of the opening 4.

### Second Embodiment

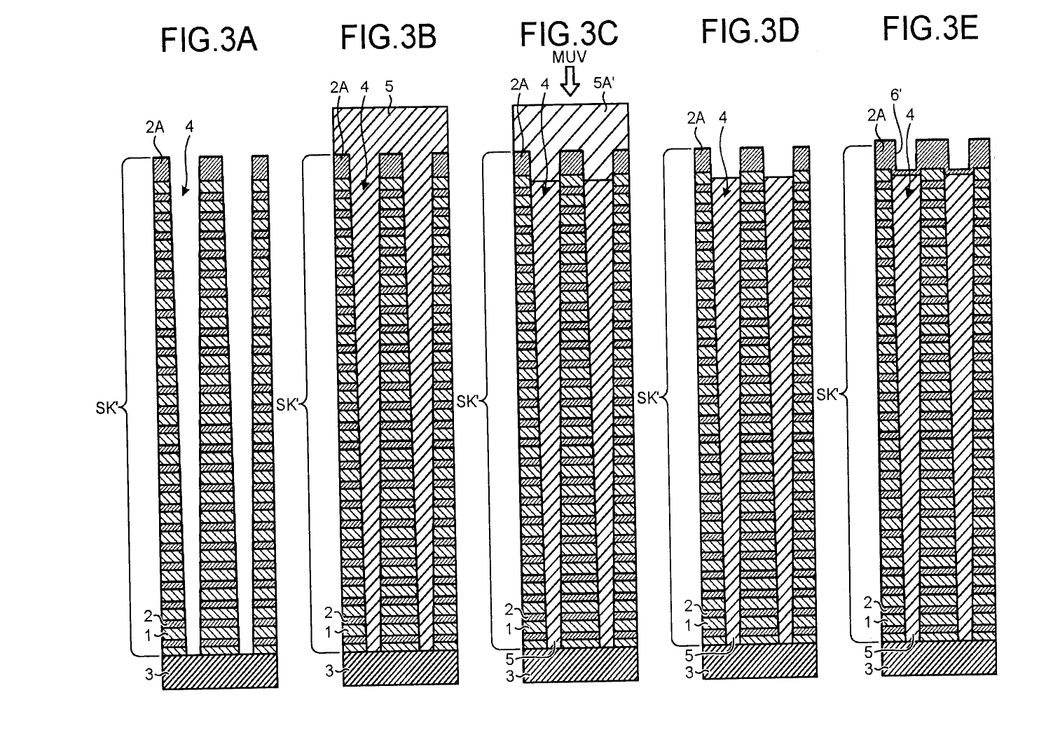

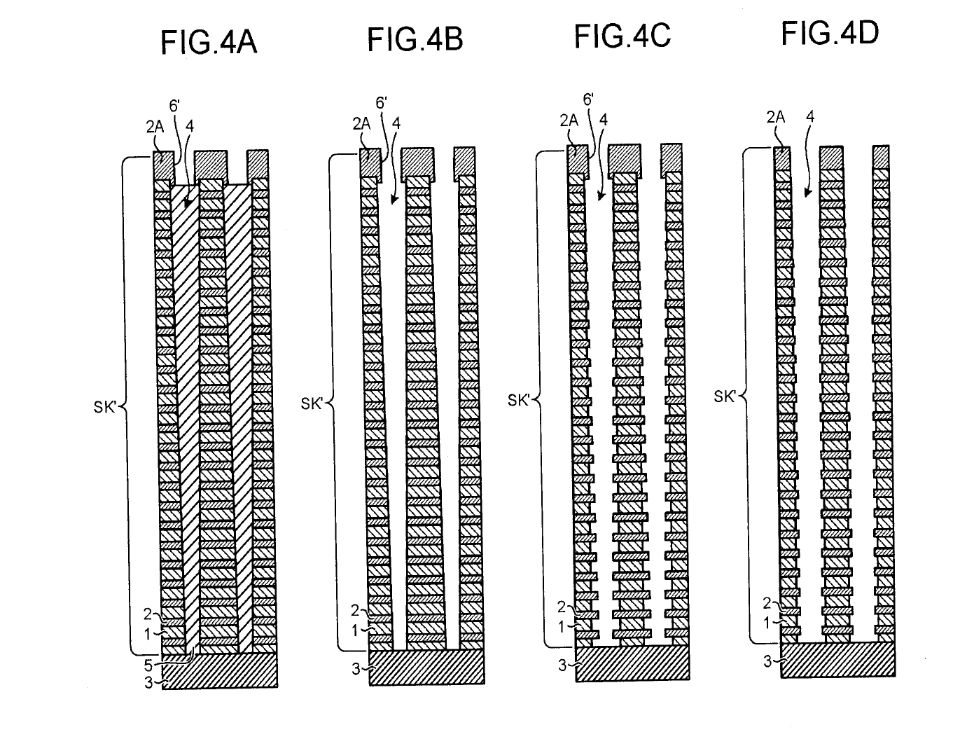

In FIGS. 3A to 3E, and FIGS. 4A to 4D, sectional views show a method of forming an opening of a semiconductor device according to a second embodiment. Here, the configuration shown in FIGS. 3A to 3E, and FIGS. 4A to 4D, is exemplified by a case where a first layer and a second layer are stacked such that 24 layers of each are present.

As shown in FIG. 3A, a stacked body SK′ is formed on an underlying layer 3 by use of a CVD method or the like, such that the first layer 1 and the second layer 2, which are made of materials different from each other, are alternately stacked in the stacked body SK′. Further, a cap layer 2A may be stacked on the uppermost layer of the stacked body SK′. The cap layer 2A may be made of the same material as that of the second layer 2. Then, patterning is performed to the stacked body SK′ by use of a photolithography technique and a dry etching technique, so that openings 4 are formed to penetrate the stacked body SK′ in the stack direction. Here, each opening 4 may be set to have a diameter smaller than the wavelength λ of exposure light MUV.

Then, as shown in FIG. 3B, a resist film 5 is uniformly formed on the entire surface of the stacked body SK′ by use of a spin coating method or the like, so that the resist film 5 is embedded in the openings 4. The resist film 5 may have sensitivity to the exposure light MUV of the wavelength λ. Here, the wavelength λ of the exposure light MUV may be set such that the cap layer 2A transmits this light but the first layer 1 or second layer 2 does not transmit this light. At this time, where d1 denotes the thickness of the first layer 1 or second layer 2, k1 denotes the extinction coefficient of the first layer 1 or second layer 2 relative to the wavelength λ, Ein denotes the light exposure amount of the resist with light of the wavelength λ, and Eth denotes the sensitivity of the resist, the following relationship is preferably satisfied:

Ein×exp(−4π·k1·d1/λ)<Eth

For example, when the first layer 1 is a silicon layer doped with an impurity and the second layer 2 and the cap layer 2A are a silicon oxide film, and the opening 4 has a diameter of about 70 nm, MUV (Middle Ultra Violet) light, such as an i-line (365 nm), may be used as the exposure light MUV. In this case, the exposure light MUV cannot be transmitted through the first layer 1.

Then, as shown in FIG. 3C, the resist film 5 is uniformly irradiated with the exposure light MUV, and the resist film 5 is thereby exposed to light, so that a latent image 5A′ is formed in the resist film 5. At this time, since the exposure light MUV cannot be transmitted through the first layer 1, the exposure light MUV is prevented from reaching the part of the resist film 5 below the uppermost layer of the first layers 1. Consequently, the latent image 5A′ is prevented from being formed in the part of the resist film 5 below the uppermost layer of the first layers 1.

Then, as shown in FIG. 3D, development is performed to the resist film 5 including the latent image 5A′ formed therein. At this time, that part of the resist film 5, in which the latent image 5A′ is formed, is removed. Here, since the latent image 5A′ is not formed in the part of the resist film 5 below the uppermost layer of the first layers 1, the setback position of the resist film 5 agrees with the position corresponding to the uppermost layer of the first layers 1, and the uniformity in setback amount of the resist film 5 can thereby be improved.

Then, as shown in FIG. 3E, a protection film 6′ is formed on the sidewall of each opening 4 above the uppermost layer of the first layers 1 by use of a CVD method or the like. The protection film 6′ may be made of a material having a smaller etching rate than those of the first layer 1 and the second layer 2. Alternatively, the protection film 6′ may be made of the same material as that of the layer having a smaller etching rate of the first layer 1 and the second layer 2. For example, when the first layer 1 is a silicon layer doped with an impurity and the second layer 2 is a silicon oxide film, the protection film 6′ may be formed of a silicon nitride film or may be formed of a silicon oxide film. Alternatively, when the first layer 1 is a silicon layer doped with an impurity at a high concentration and the second layer 2 is a silicon layer doped with an impurity at a low concentration, the protection film 6′ may be formed of a silicon oxide film.

Then, as shown in FIG. 4A, the protection film 6′ is etched back, so that, while the protection film 6′ on the sidewall of each opening 4 above the uppermost layer of the first layers 1 is left, the surface of the part of the resist film 5 below the uppermost layer of the first layers 1 is exposed.

Then, as shown in FIG. 4B, the part of the resist film 5 below the uppermost layer of the first layers 1 is removed by use of an ashing method or the like.

Then, as shown in FIG. 4C, the sidewall of each first layer 1 at and below the uppermost layer of the first layers 1 is set back in the lateral direction by use of an isotropic etching method or the like. This setback amount of the first layer 1 is preferably set such that the diameter of the opening 4 above the uppermost layer of the first layers 1 agrees with the diameter of the opening 4 below the uppermost layer of the first layers 1.

Then, as shown in FIG. 4D, the sidewall of each second layer 2 below the uppermost layer of the first layers 1 is set back in the lateral direction by use of an isotropic etching method or the like. This setback amount of the second layer 2 is preferably set such that the diameter of the opening 4 above the uppermost layer of the first layers 1 agrees with the diameter of the opening 4 below the uppermost layer of the first layers 1. Here, when the second layer 2 and the protection film 6′ are made of the same material, the protection film 6′ can be removed at the same time when the second layers 2 are set back, and so the number of process steps can be reduced.

In this embodiment, the wavelength λ of the exposure light MUV is set such that the cap layer 2A transmits this light but the first layer 1 or second layer 2 does not transmit this light, so that, when light of the wavelength λ is incident into each opening 4, the light is prevented from being transmitted below the uppermost layer of the first layers 1 or second layers 2. Consequently, for the resist film 5 embedded in each opening 4, exposure to light can be stopped at the position corresponding to the uppermost layer of the first layers 1 or second layers 2, so that the uniformity in setback amount of the resist film 5 embedded in the openings 4 can be improved. As a result, the uniformity in height where the openings 4 are exposed from the protection film 6′ is improved, and the uniformity in etching amount to the openings 4 in the lateral direction can be improved, so that the uniformity in width of the openings 4 can thereby be improved.

It should be noted that the opening 4 may have a flat shape. A flat opening 4 may be exemplified by an elliptical hole of a slit. In such a case, the polarization direction of the exposure light MUV is preferably set perpendicular to the longitudinal direction of the opening 4.

### Third Embodiment

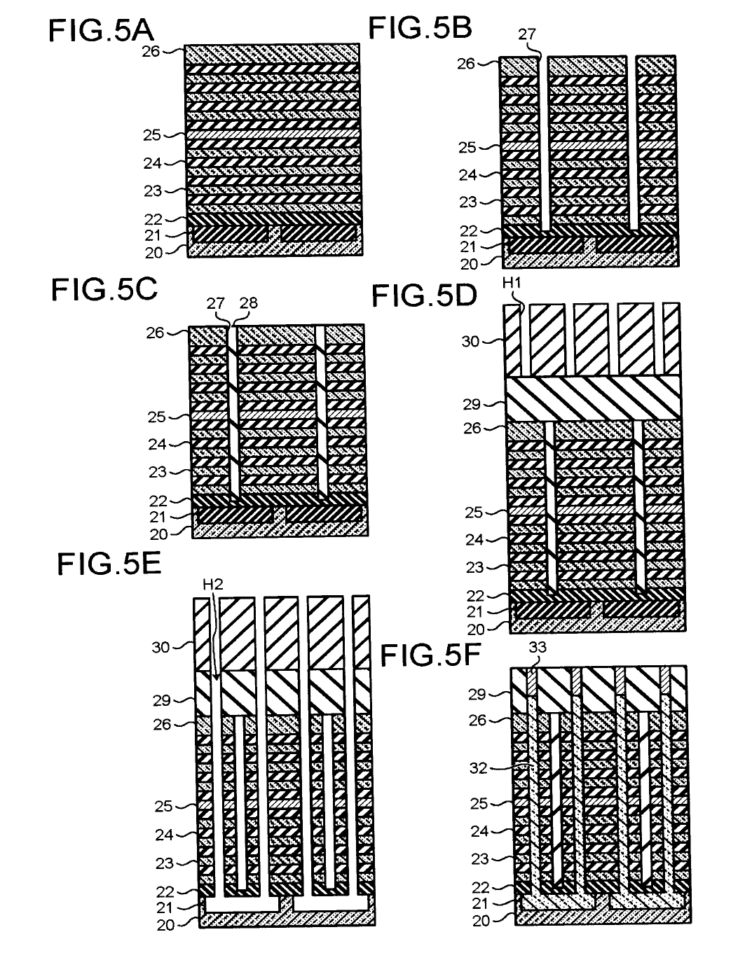

In FIGS. 5A to 5F, sectional views show a method of manufacturing a memory cell array of a nonvolatile semiconductor memory device according to a third embodiment. Here, this third embodiment is exemplified by a case where 8 layers of a memory cell are stacked and a selection gate line is further stacked thereon.

As shown in FIG. 5A, connecting portions 21 are formed in an underlying layer 20. Then, a sacrificial film is embedded in the connecting portions 21, and then an interlayer insulating film 22 is formed on the underlying layer 20. Here, the underlying layer 20 may be formed of a semiconductor substrate, for example. The material of the interlayer insulating film 22 may be a silicon oxide film, for example. The sacrificial film embedded in the connecting portions 21 may be made of a material that has a selection ratio smaller than that of the interlayer insulating film 22.

Then, an impurity-doped silicon layer 23 and an interlayer insulating layer 24 are alternately stacked by use of a CVD method or the like. At this time, film formation is performed such that one of layers of the impurity-doped silicon layer 23 is replaced with a light non-transmitting film 25. The light non-transmitting film 25 may be made of a material that does not transmit light of a wavelength λ used for light exposure of a resist. The material of the light non-transmitting film 25 may be a metal-containing film, such as tungsten, tungsten silicide, titanium, or titanium nitride, or may be a carbon film. The interlayer insulating layer 24 may be formed of a BSG (Boron Silicate Glass) film or may be formed of a silicon oxide film, for example. In this respect, the material of the insulating layer 24 is preferably selected to provide an etching rate equal to that of the impurity-doped silicon layer 23 as far as possible. Further, the impurity of the impurity-doped silicon layer 23 may be B, 2, or As. Then, an impurity-doped silicon layer 26 is formed on the uppermost layer of the interlayer insulating layers 24 by use of a CVD method or the like. Here, the impurity-doped silicon layers 23 may be used for word lines, and the impurity-doped silicon layer 26 may be used for a selection gate line.

Then, as shown in FIG. 5B, patterning is performed to the impurity-doped silicon layers 26 and 23, the interlayer insulating films 24 and 22, and the light non-transmitting film 25, so that slits 27 are formed in the impurity-doped silicon layers 26 and 23, the interlayer insulating films 24 and 22, and the light non-transmitting film. 25, to divide the impurity-doped silicon layers 26 and 23, the interlayer insulating films 24 and 22, and the light non-transmitting film 25 in the column direction. Here, the process steps shown in FIGS. 1A to 1E, and FIGS. 2A to 2D, may be applied to the formation of the slits 27. Alternatively, the process steps shown in FIGS. 3A to 3E, and FIGS. 4A to 4D, may be applied thereto. Consequently, the uniformity in width of the slits 27 can be improved.

Then, as shown in FIG. 5C, an insulating body 28 is embedded in the slits 27. Here, the material of the insulating body 28 may be a silicon oxide film, for example.

Then, as shown in FIG. 5D, an interlayer insulating film 29 is formed on the impurity-doped silicon layer 26 by use of a CVD method or the like. Then, a mask pattern 30 including openings H1 is formed on the interlayer insulating film 29. Here, the material of the mask pattern 30 may be a BSG film or may be a TEOS (tetraethoxysilane: Si(OC₂H₅)₄) film.

Then, as shown in FIG. 5E, etching is performed through the mask pattern 30 to the impurity-doped silicon layers 26 and 23, the interlayer insulating films 29, 24, and 22, and the light non-transmitting film 25, so that memory holes H2 are formed in the impurity-doped silicon layers 26 and 23, the interlayer insulating films 29, 24, and 22, and the light non-transmitting film 25. Here, the process steps shown in FIGS. 1A to 1E, and FIGS. 2A to 2D, may be applied to the formation of the memory holes H2. Alternatively, the process steps shown in FIGS. 3A to 3E, and FIGS. 4A to 4D, may be applied thereto. Consequently, the uniformity in diameter of the memory holes H2 can be improved. Further, the interlayer insulating film 29 and the mask pattern 30 may be made to correspond to the cap layer 2A shown in FIG. 1A. Then, etching is preformed through the memory holes H2 to the sacrificial film in the connecting portions 21, so that the sacrificial film in the connecting Portions 21 is removed.

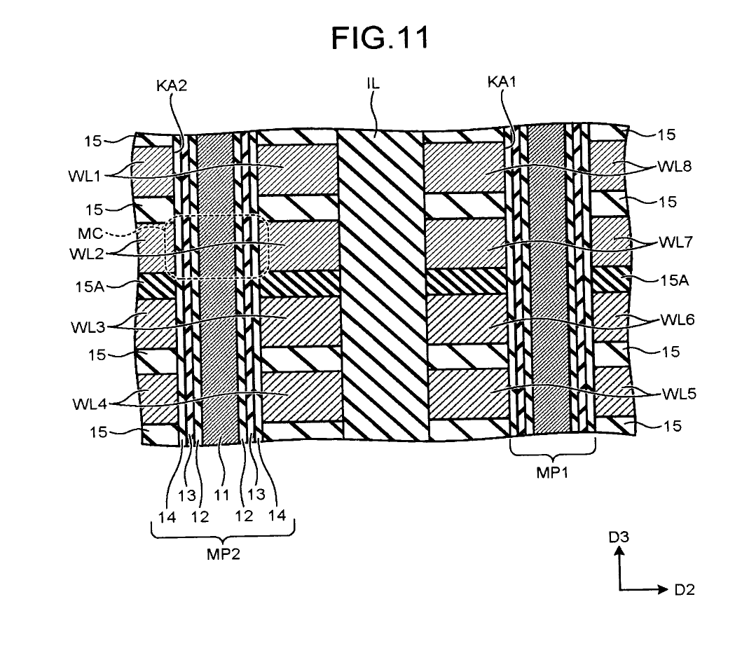

Then, as shown in FIG. 5F, columnar bodies 32 are embedded in the memory holes H2 and the connecting portions 21 by use of a CVD method or the like. Further, the columnar bodies 32 embedded in the interlayer insulating film 29 are partly removed, and plugs 33 are respectively embedded in the portions formed by this removal. Here, each columnar body 32 may have the same configuration as that of a columnar body MP2 shown in FIG. 11.

As a method of forming the columnar bodies 32, a block insulating film 14 is formed on the inner surface of each memory hole H by use of a CVD method or the like. Then, a charge trap layer 13 is formed on the surface of the block insulating film 14 in the memory hole H2 by use of a CVD method or the like. Then, a tunnel insulating film 12 is formed on the surface of the charge trap layer 13 inside the memory hole H2 by use of a CVD method or the like. Then, a columnar semiconductor body 11 is embedded through the tunnel insulating film 12 in the memory hole H2 by use of a CVD method or the like. Here, a channel layer may be formed in the columnar semiconductor body 11. Alternatively, a semiconductor layer may be formed, in place of the columnar semiconductor body 11 embedded in the memory hole H2, on the surface of the tunnel insulating film 12, and thereafter a columnar insulating body is embedded in the memory hole H2.

### Fourth Embodiment

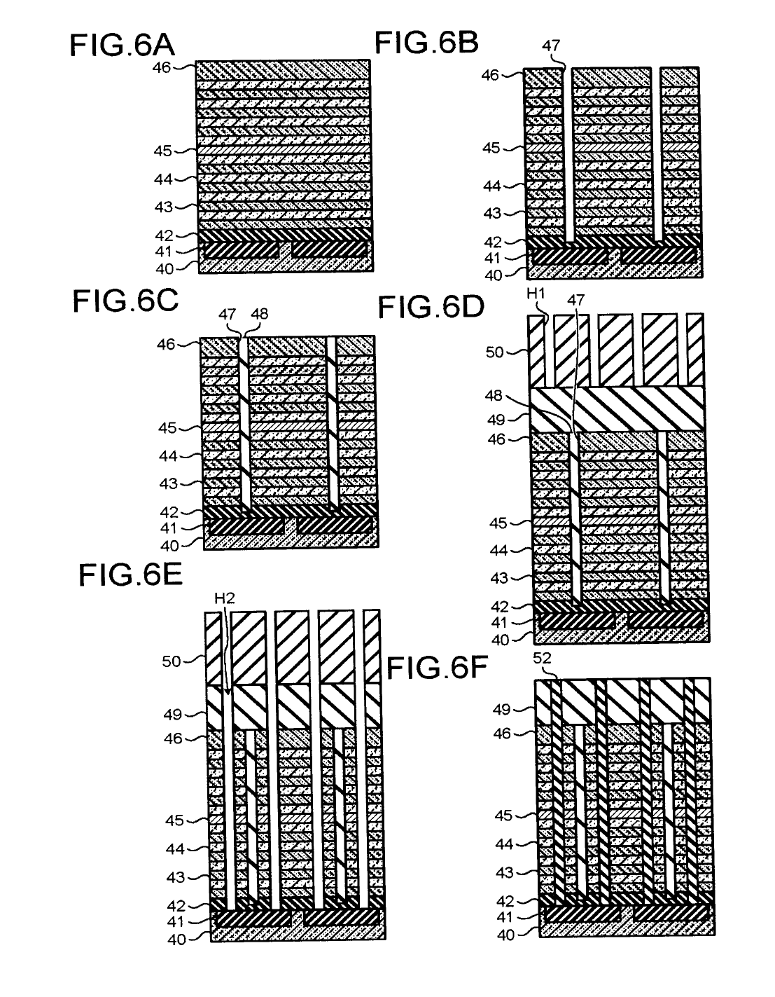

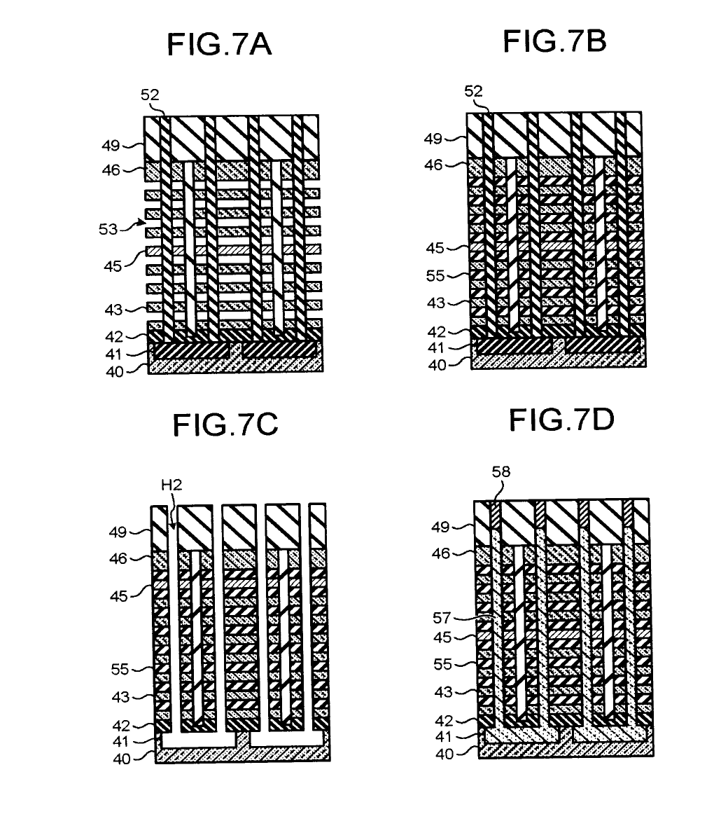

In FIGS. 6A to 6F, and FIGS. 7A to 7D, sectional views show a method of manufacturing a memory cell array of a nonvolatile semiconductor memory device according to a fourth embodiment. Here, this fourth embodiment is exemplified by a case where 8 layers of a memory cell are stacked and a selection gate line is further stacked thereon.

As shown in FIG. 6A, connecting portions 41 are formed in an underlying layer 40. Then, a sacrificial film is embedded in the connecting portions 41, and then an interlayer insulating film 42 is formed on the underlying layer 40. Here, the underlying layer 40 may be formed of a semiconductor substrate, for example. The material of the interlayer insulating film 42 may be a silicon oxide film, for example. The sacrificial film embedded in the connecting portions 41 may be made of a material that has a selection ratio smaller than that of the interlayer insulating film 42.

Then, an impurity-doped silicon layer 43 and an impurity-undoped silicon layer 44 are alternately stacked by use of a CVD method or the like. At this time, film formation is performed such that one of layers of the impurity-doped silicon layer 43 is replaced with a light non-transmitting film 45. The light non-transmitting film 45 may be made of a material that does not transmit light of a wavelength λ used for light exposure of a resist. The material of the light non-transmitting film 45 may be a metal-containing film, such as tungsten, tungsten silicide, titanium, or titanium nitride, or may be a carbon film. Then, an impurity-doped silicon layer 46 is formed on the uppermost layer of the impurity-undoped silicon layers 44 by use of a CVD method or the like. Here, the impurity-doped silicon layers 43 may be used for word lines, and the impurity-doped silicon layer 46 may be used for a selection gate line.

Then, as shown in FIG. 6B, patterning is performed to the impurity-doped silicon layers 43 and 46, the impurity-undoped silicon layers 44, and the light non-transmitting film 45, so that slits 47 are formed in the impurity-doped silicon layers 43 and 46, the impurity-undoped silicon layers 44, and the light non-transmitting film 45, to divide the impurity-doped silicon layers 43 and 46, the impurity-undoped silicon layers 44, and the light non-transmitting film 45 in the column direction. Here, the process steps shown in FIGS. 1A to 1E, and FIGS. 2A to 2D, may be applied to the formation of the slits 47. Alternatively, the process steps shown in FIGS. 3A to 3E, and FIGS. 4A to 4D, may be applied thereto. Consequently, the uniformity in width of the slits 47 can be improved.

Then, as shown in FIG. 6C, an insulating body 48 is embedded in the slits 47. Here, the material of the insulating body 48 may be a silicon oxide film, for example.

Then, as shown in FIG. 6D, an interlayer insulating film 49 is formed on the impurity-doped silicon layer 46 by use of a CVD method or the like. Then, a mask pattern 50 including openings H1 is formed on the interlayer insulating film 49. Here, the material of the mask pattern 50 may be a BSG film or may be a TEOS film.

Then, as shown in FIG. 6E, etching is performed through the mask pattern 50 to the impurity-doped silicon layers 43 and 46, the impurity-undoped silicon layers 44, the interlayer insulating films 42 and 49, and the light non-transmitting film 45, so that memory holes H2 are formed in the impurity-doped silicon layers 43 and 46, the impurity-undoped silicon layers 44, the interlayer insulating films 42 and 49, and the light non-transmitting film 45. Here, the process steps shown in FIGS. 1A to 1E, and FIGS. 2A to 2D, may be applied to the formation of the memory holes H2. Alternatively, the process steps shown in FIGS. 3A to 3E, and FIGS. 4A to 4D, may be applied thereto. Consequently, the uniformity in diameter of the memory holes H2 can be improved. Further, the impurity-doped silicon layer 46 and the interlayer insulating film 49 may be made to correspond to the cap layer 2A shown in FIG. 1A.

Then, as shown in FIG. 6F, a sacrificial film 52 is embedded in the memory holes H2 by use of a CVD method or the like, then the sacrificial film 52 is planarized by use of a CMP method or the like, and then the mask pattern 50 is removed. Here, the material of the sacrificial film 52 may be a silicon oxide film or silicon nitride film.

Then, as shown in FIG. 7A, the impurity-undoped silicon layers 44 are preferentially etched by use of a wet etching method or the like to remove the impurity-undoped silicon layer 44, so that gaps 53 are respectively formed between the impurity-doped silicon layers 43 and above and below the light non-transmitting film 45. Here, in order to reduce the resistivity of the impurity-doped silicon layers 43 and 46, the impurity-doped silicon layers 43 and 46 may be shielded after the impurity-undoped silicon layers 44 are removed.

Then, as shown in FIG. 7B, interlayer insulating films 55 are respectively embedded in the gaps 53 by use of an ALD-CVD method or the like.

Then, as shown in FIG. 7C, the sacrificial film 52 in each memory hole H2 is removed, so that the sidewalls of the impurity-doped silicon layers 43 and 46 and the light non-transmitting film 45 are exposed. Further, etching is preformed through the memory holes H2 to the sacrificial film in the connecting portions 41, so that the sacrificial film in the connecting portions 41 is removed.

Then, as shown in FIG. 7D, columnar bodies 57 are embedded in the memory holes H2 and the connecting portions 41 by use of a CVD method or the like. Further, the columnar bodies 57 embedded in the interlayer insulating film 49 are partly removed, and plugs 58 are respectively embedded in the portions formed by this removal. Here, each columnar body 57 may have the same configuration as that of a columnar body MP2 shown in FIG. 11.

In the method according to the embodiment described above, one layer of the impurity-doped silicon layers 43 is replaced with the light non-transmitting film 45, but one layer of the impurity-undoped silicon layers 44 may alternatively be replaced with the light non-transmitting film 45. In this case, when the impurity-undoped silicon layers 44 are removed, the light non-transmitting film 45 can be removed together. Consequently, the light non-transmitting film 45 is replaced with an interlayer insulating film 55 in the process step shown in FIG. 7B, and thus the light non-transmitting film 45 becomes unnecessary to be used as a word line.

### Fifth Embodiment

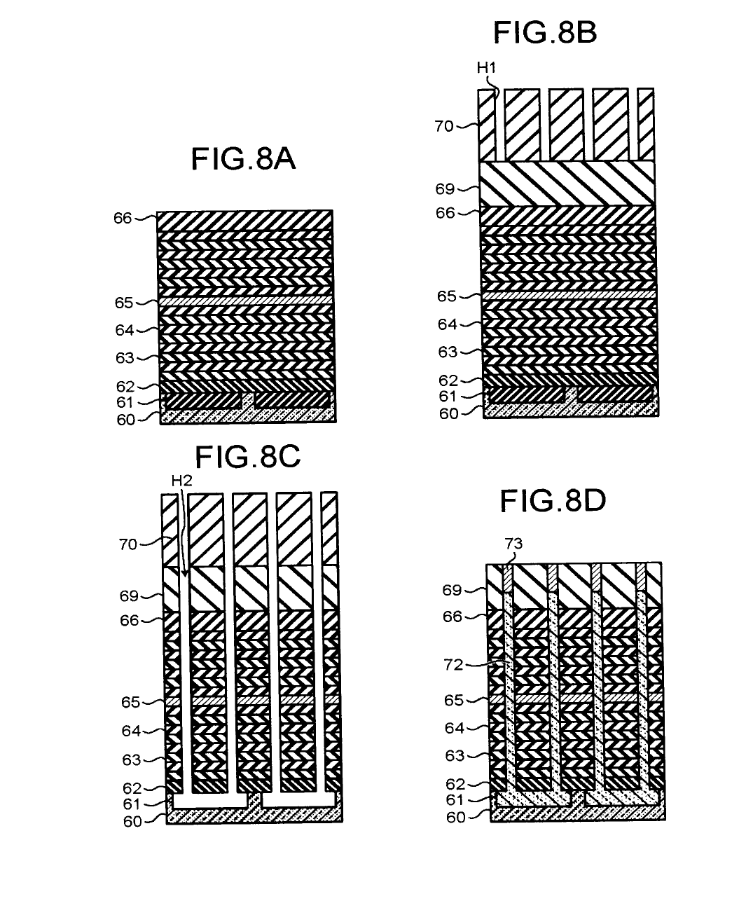

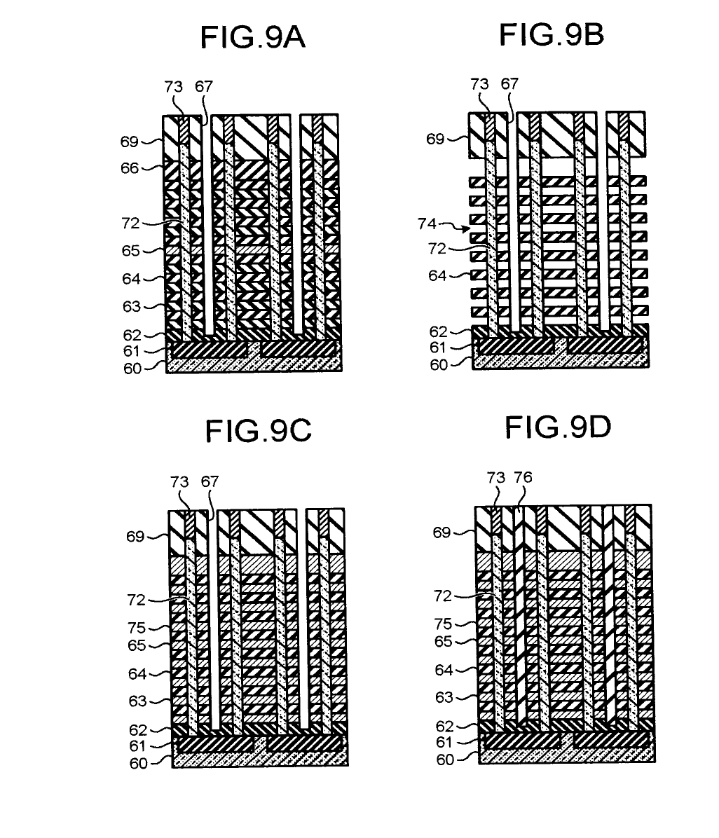

In FIGS. 8A to 8D, and FIGS. 9A to 9D, sectional views show a method of manufacturing a memory cell array of a nonvolatile semiconductor memory device according to a fifth embodiment. Here, this fifth embodiment is exemplified by a case where 8 layers of a memory cell are stacked and a selection gate line is further stacked thereon.

As shown in FIG. 8A, connecting portions 61 are formed in an underlying layer 60. Then, a sacrificial film is embedded in the connecting portions 61, and then an interlayer insulating film 62 is formed on the underlying layer 60. Here, the underlying layer 60 may be formed of a semiconductor substrate, for example. The material of the interlayer insulating film 62 may be a silicon oxide film, for example. The sacrificial film embedded in the connecting portions 61 may be made of a material that has a selection ratio smaller than that of the interlayer insulating film 62.

Then, a silicon nitride film 63 and a silicon oxide film 64 are alternately stacked by use of a CVD method or the like. At this time, film formation is performed such that one of layers of the silicon oxide film 64 is replaced with a light non-transmitting film 65. The light non-transmitting film 65 may be made of a material that does not transmit light of a wavelength λ used for light exposure of a resist. The material of the light non-transmitting film 65 may be a polycrystalline silicon film, may be a metal-containing film, such as tungsten, tungsten silicide, titanium, or titanium nitride, or may be a carbon film. Then, a silicon nitride film 66 is formed on the uppermost layer of the silicon oxide films 64 by use of a CVD method or the like.

Then, as shown in FIG. 88, an interlayer insulating film 69 is formed on the silicon nitride film 66 by use of a CVD method or the like. Here, the material of the interlayer insulating film 69 may be a silicon oxide film. Then, a mask pattern 70 including openings H1 is formed on the interlayer insulating film 69. Here, the material of the mask pattern 70 may be a BSG film or may be a TEOS film.

Then, as shown in FIG. 8C, etching is performed through the mask pattern 70 to the silicon nitride films 63 and 66, the silicon oxide films 64, the interlayer insulating films 62 and 69, and the light non-transmitting film 65, so that memory holes H2 are formed in the silicon nitride films 63 and 66, the silicon oxide films 64, the interlayer insulating films 62 and 69, and the light non-transmitting film 65. Here, the process steps shown in FIGS. 1A to 1E, and FIGS. 2A to 2D, may be applied to the formation of the memory holes H2. Alternatively, the process steps shown in FIGS. 3A to 3E, and FIGS. 4A to 4D, may be applied thereto. Consequently, the uniformity in diameter of the memory holes H2 can be improved. Further, etching is performed through the memory holes H2 to the sacrificial film in the connecting portions 61, so that the sacrificial film in the connecting portions 61 is removed.

Then, as shown in FIG. 8D, columnar bodies 72 are embedded in the memory holes H2 and the connecting portions 61 by use of a CVD method or the like. Further, the columnar bodies 72 embedded in the interlayer insulating film 69 are partly removed, and plugs 73 are respectively embedded in the portions formed by this removal. Here, each columnar body 72 may have the same configuration as that of a columnar body MP2 shown in FIG. 11.

Then, as shown in FIG. 9A, patterning is performed to the silicon nitride films 63 and 66, the silicon oxide films 64, the interlayer insulating film 69, and the light non-transmitting film 65, so that slits 67 are formed in the silicon nitride films 63 and 66, the silicon oxide films 64, the interlayer insulating film 69, and the light non-transmitting film 65, to divide the silicon nitride films 63 and 66, the silicon oxide films 64, the interlayer insulating film 69, and the light non-transmitting film 65 in the column direction. Here, the process steps shown in FIGS. 1A to 1E, and FIGS. 2A to 2D, may be applied to the formation of the slits 67. Alternatively, the process steps shown in FIGS. 3A to 3E, and FIGS. 4A to 4D, may be applied thereto. Consequently, the uniformity in width of the slits 67 can be improved.

Then, as shown in FIG. 9B, the silicon nitride films 63 and 66 and the light non-transmitting film 65 are preferentially etched by use of a wet etching method or the like to remove the silicon nitride films 63 and 66 and the light non-transmitting film 65, so that gaps 74 are respectively formed between the silicon nitride films 64 and below the interlayer insulating film 69.

Then, as shown in FIG. 9C, conductive films 75 are respectively embedded in the gaps 74 by use of an ALD-CVD method or the like. The material of the conductive films 75 may be tungsten, for example.

Then, as shown in FIG. 9D, insulating bodies 76 are embedded in the slits 67. Here, the material of the insulating bodies 76 is a silicon oxide film, for example.

In the method according to the embodiment described above, one layer of the silicon nitride films 63 is replaced with the light non-transmitting film 65, but one layer of the silicon oxide films 64 may alternatively be replaced with the light non-transmitting film 65.

### Sixth Embodiment

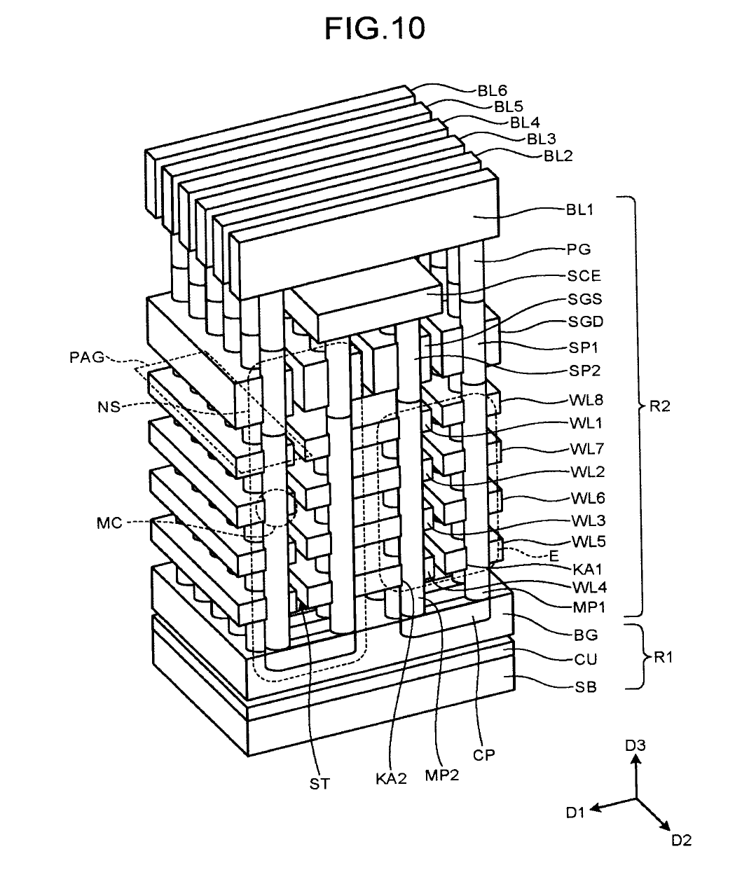

FIG. 10 is a perspective view showing a schematic configuration example of a memory cell array of a nonvolatile semiconductor memory device according to a sixth embodiment. Here, in the example shown in FIG. 10, 4 layers of a memory cell MC stacked are folded back at the lower end, so that 8 memory cells MC are connected in series by this method to form a NAND string NS. Further, in the example shown in FIG. 10, interlayer insulating films interposed between word lines WL1 to WL4 and between word lines WL5 to WL8 are not shown.

As shown in FIG. 10, a semiconductor substrate SB is provided with a circuit region R1, and a memory region R2 is arranged on the circuit region R1. In this case, a substrate provided with the circuit region R1 and a substrate provided with the memory region R2 may be individually prepared.

Here, in the circuit region R1, a circuit layer CU is formed on the semiconductor substrate SB. A back gate layer BG is formed on the circuit layer CU, and connection layers CP are formed in the back gate layer BG. On each connection layer CP, columnar bodies MP1 and MP2 are arranged adjacent to each other, such that the lower ends of the columnar bodies MP1 and MP2 are connected to each other by the connection layer CP. Further, above each connection layer CP, the word lines WL4 to WL1 are stacked as 4 layers alternately with an interlayer insulating film in a stack direction D3, and the word lines WL5 to WL8 are stacked as 4 layers alternately with an interlayer insulating film in the stack direction D3, such that the word lines WL5 to WL8 are respectively adjacent to the word lines WL4 to WL1. Here, for example, the word lines WL1 to WL8 may be formed of a silicon layer doped with an impurity or a tungsten layer. A selection gate line SGS is stacked through an interlayer insulating film on the word line WL1 serving as the uppermost layer, and a selection gate line SGD is stacked through an interlayer insulating film on the word line WL8 serving as the uppermost layer. Here, the selection gate lines SGS and SGD may be formed of a silicon layer doped with an impurity or a tungsten layer.

Here, in this stacked body, a memory hole KA2 is formed to penetrate the word lines WL4 to WL1 and the selection gate line SGS, and a memory hole KA1 is formed to penetrate the word lines WL5 to WL8 and the selection gate line SGD. Further, the columnar body MP1 is provided to penetrate the word lines WL5 to WL8 through the memory hole KA1, so that memory cells MC are configured respectively at the word lines WL5 to WL8, and the columnar body MP2 is provided to penetrate the word lines WL1 to WL4 through the memory hole KA2, so that memory cells MC are configured respectively at the word lines WL1 to WL4. Further, a slit ST is formed between the word lines WL1 to WL4 and the word lines WL5 to WL8, so that the word lines WL1 to WL8 are divided in accordance with pages PAG. At this time, the word lines WL1 to WL8 may be formed in a row direction D1. Each of the pages PAG is a unit of writing data to memory cells MC or a unit of reading data from memory cells MC. Further, columnar bodies SP1 and SP2 are respectively formed on the columnar bodies MP1 and MP2. Here, the columnar body SP1 is provided to penetrate the selection gate line SGD through the memory hole KA1, and the columnar body SP2 is provided to penetrate the selection gate line SGS through the memory hole KA2, so that the NAND string NS is formed.

Further, a source line SCE is provided above the selection gate line SGS and is connected to the columnar bodies SP2, and bit lines BL1 to BL6 are formed in a column direction D1 above the source line SCE and are respectively connected to the columnar bodies SP1 through plugs PG. Here, the columnar bodies MP1 and MP2 may be arranged at the intersections between the bit lines BL1 to BL6 and the word lines WL1 to WL6.

FIG. 11 is a sectional view showing a portion E of FIG. 10 in an enlarged state.

As shown in FIG. 11, an insulating body IL is embedded between the word lines WL1 to WL4 and the word lines WL5 to WL8. Interlayer insulating films 15 are respectively formed between the word lines WL1 to WL4 and between the word lines WL5 to WL8. At this time, one interlayer insulating film 15 of the interlayer insulating films 15 is replaced with an interlayer film 15A. The interlayer film 15A is preferably arranged at a middle position in the stack direction D3 of the stacked body composed of the word lines WL1 to WL8 and the interlayer insulating films 15. In the example shown in FIG. 11, one interlayer insulating film 15 present between the word lines WL2 and WL7 and between the word lines WL3 and WL6 is replaced with the interlayer film 15A. The material of the interlayer insulating films 15 may be a silicon oxide film. The interlayer film 15A may be made of a material that does not transmit light of a wavelength λ. The wavelength λ may be set such a resist to be embedded in the memory holes KA1 and KA2 or the slit ST has sensitivity to the wavelength λ. The wavelength λ may be set to fall within the ultraviolet region including a g-line (436 nm), an i-line (365 nm), KrF excimer laser (248 nm), ArF excimer laser (193 nm), and F2 excimer laser (157 nm). The wavelength λ may be set to fall within an extreme ultraviolet region of a wavelength of 10 nm or less. At this time, the diameter of the memory holes KA1 and KA2 or the width of the slit ST may be set smaller than the wavelength λ. The material of the interlayer film 15A may be a polycrystalline silicon film, metal-containing film, or carbon film. Alternatively, the material of the interlayer film 15A may be an insulating body, such as metal oxide. Here, when the material of the interlayer film 15A is an insulating body, it is possible to prevent a memory cell MC in contact with the interlayer film 15A from becoming unusable. In this respect, where d1 denotes the thickness of the interlayer film 15A, k1 denotes the extinction coefficient of the interlayer film 15A relative to the wavelength λ, Ein denotes the light exposure amount of the resist with light of the wavelength Δ, and Eth denotes the sensitivity of the resist, the following relationship is preferably satisfied:

Ein×exp(−4π·k1·d1/λ)<Eth

Further, the memory hole KA2 is formed to penetrate the word lines WL1 to WL4 and the interlayer insulating films 15 in the stack direction D3, and the memory hole KA1 is formed to penetrate the word lines WL5 to WL8 and the interlayer insulating films 15 in the stack direction. The columnar body MP1 is formed in the memory hole KA1, and the columnar body MP2 is formed in the hole KA2.

At the center of each of the columnar bodies MP1 and MP2, a columnar semiconductor body 11 is present. A tunnel insulating film 12 is formed between the inner surface of each of the memory holes KA1 and KA2 and the columnar semiconductor body 11, a charge trap layer 13 is formed between the inner surface of each of the memory holes KA1 and KA2 and the tunnel insulating film 12, and a block insulating film 14 is formed between the inner surface of each of the memory holes KA1 and KA2 and the charge trap layer 13. The columnar semiconductor body 11 may be made of a semiconductor, such as Si, for example. The tunnel insulating film 12 and the block insulating film 14 may be formed of a silicon oxide film, for example. The charge trap layer 13 may be formed of a silicon nitride film or an ONO film (a 3-layer structure consisting of a silicon oxide film/a silicon nitride film/a silicon oxide film), for example.

In this embodiment, one interlayer insulating film 15 of the interlayer insulating films 15 is replaced with the interlayer film 15A, so that, when light of the wavelength 2 is incident into each of the memory holes KA1 and KA2 or slit ST, the light is prevented from being transmitted below the interlayer film 15A. Consequently, for the resist embedded in each of the memory holes KA1 and KA2 or slit ST, exposure to light can be stopped at the position corresponding to the interlayer film 15A, so that the uniformity in setback amount of the resist embedded in the memory holes KA1 or KA2 or the slits ST can be improved. As a result, the uniformity in processing of the memory holes KA1 or KA2 or the slits ST, which is performed by use of the resist thus set back, is improved, and the uniformity in diameter of the memory holes KA1 or KA2 or in width of the slits ST can thereby be improved.

### Seventh Embodiment

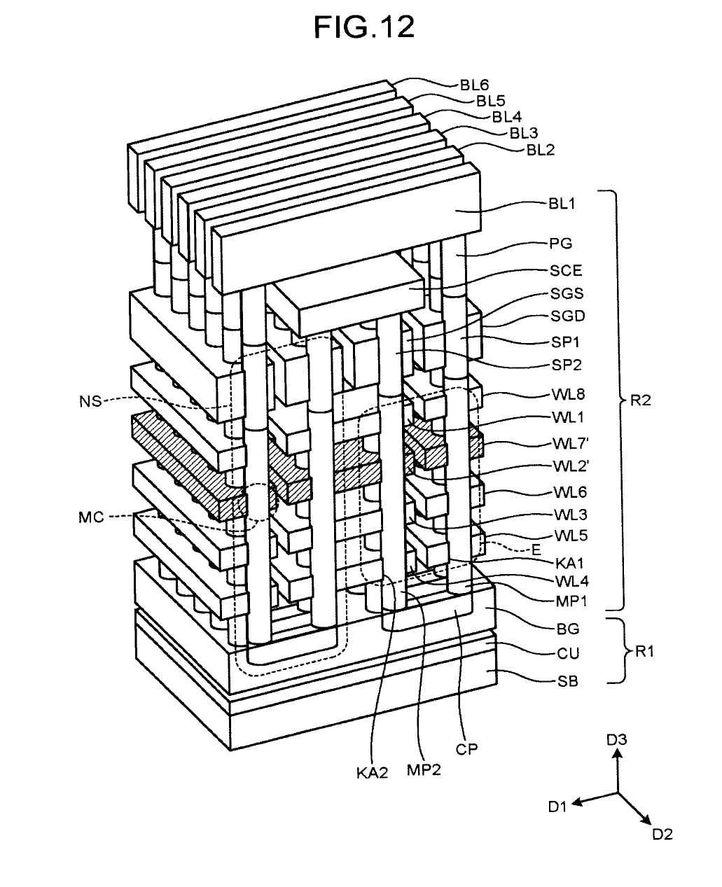

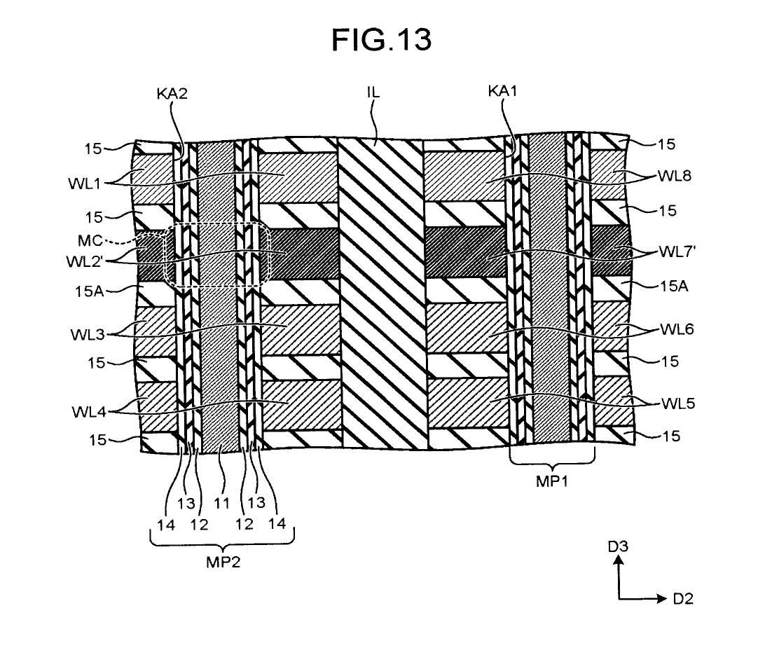

FIG. 12 is a perspective view showing a schematic configuration example of a memory cell array of a nonvolatile semiconductor memory device according to a seventh embodiment. FIG. 13 is a sectional view showing a portion E of FIG. 12 in an enlarged state.

In the example shown in FIGS. 10 and 11, an interlayer insulating film 15 is replaced with the interlayer film 15A. On the other hand, in the example shown in FIGS. 12 and 13, the word lines WL2 and WL7 corresponding to one layer of the layers of the word lines WL1 to WL8 are replaced with word lines WL2′ and WL7′. The word lines WL2′ and WL7′ may be made of a material that does not transmit light of the wavelength λ. The material of the word lines WL2′ and WL7′ may be a polycrystalline silicon film, metal-containing film, or carbon film. Here, when the material of the word lines WL2′ and WL7′ is a conductive body, it is possible to prevent a memory cell MC including the word lines WL2′ and WL7′ from becoming unusable. In this respect, where d1 denotes the thickness of the word lines WL2′ and WL7′, k1 denotes the extinction coefficient of the word lines WL2′ and WL7′ relative to the wavelength λ, Ein denotes the light exposure amount of the resist with light of the wavelength λ, and Eth denotes the sensitivity of the resist, the following relationship is preferably satisfied:

Ein×exp(−4π·k1·d1/λ)<Eth

In this embodiment, the word lines WL2 and WL7 corresponding to one layer of the layers of the word lines WL1 to WL8 are replaced with word lines WL2′ and WL7′, so that, when light of the wavelength λ is incident into each of the memory holes KA1 and KA2 or slit ST, the light is prevented from being transmitted below the word lines WL2′ and WL7′. Consequently, for the resist embedded in each of the memory holes KA1 and KA2 or slit ST, exposure to light can be stopped at the position corresponding to the word lines WL2′ and WL7′, so that the uniformity in setback amount of the resist embedded in the memory holes KA1 or KA2 or the slits ST can be improved. As a result, the uniformity in processing of the memory holes KA1 or KA2 or the slits ST, which is performed by use of the resist thus set back, is improved, and the uniformity in diameter of the memory holes KA1 or KA2 or in width of the slits ST can thereby be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked body formed such that a first layer and a second layer, which are made of materials different from each other, are alternately stacked, and one of layers of the first layer or one of layers of the second layer is replaced with a third layer that does not transmit light of a wavelength λ; and
an opening configured to penetrate the stacked body in a stack direction and has a diameter or width smaller than the wavelength λ.

2. The semiconductor device of claim 1, wherein the light of the wavelength λ is ultraviolet.

3. The semiconductor device of claim 1, wherein the third layer is arranged at a middle position of the stacked body in the stack direction.

4. The semiconductor device of claim 1, wherein the opening includes a step at a position corresponding to the third layer.

5. The semiconductor device of claim 1, wherein,
were d1 denotes a thickness of the third layer, k1 denotes an extinction coefficient of the third layer relative to the wavelength λ, Ein denotes a light exposure amount of a resist with the light of the wavelength λ, and Eth denotes sensitivity of the resist,
a relationship of “Ein×exp(−4π·k1·d1/λ)<Eth” is satisfied.

6. The semiconductor device of claim 1, wherein the third layer is a polycrystalline silicon film, metal-containing film, or carbon film.

7. The semiconductor device of claim 1, wherein the first layer is a silicon layer doped with an impurity, the second layer is an interlayer insulating film, and the first layer is used as a word line of a memory cell.

8. The semiconductor device of claim 7, wherein the opening includes a memory hole that penetrates the word line, and a slit that divides the word line in accordance with a page unit.

9. The semiconductor device of claim 8, comprising:
a channel layer provided in the memory hole along the stack direction of the stacked body;
a tunnel insulating film provided between an inner surface of the memory hole and the channel layer;
a charge trap layer provided between the inner surface of the memory hole and the tunnel insulating film; and
a block insulating film provided between the inner surface of the memory hole and the charge trap layer.

10. A manufacturing method of a semiconductor device, the method comprising:
forming a stacked body such that a first layer and a second layer, which are made of materials different from each other, are alternately stacked, and one of layers of the first layer or one of layers of the second layer is replaced with a third layer that does not transmit light of a wavelength λ;
forming an opening, which has a diameter or width smaller than the wavelength λ, through the stacked body in a stack direction;
forming a resist, which has sensitivity to the light of the wavelength λ, in the opening;
irradiating the resist formed in the opening with the light of the wavelength λ, and thereby forming a latent image in part of the resist at an upper side of the opening;
removing the part of the resist, in which the latent image is formed, and thereby exposing a sidewall of the opening at the upper side;
forming a protection film that covers the sidewall of the opening at the upper side;
removing part of the resist at a lower side of the opening, and thereby exposing a sidewall of the opening at the lower side; and
setting back the sidewall of the opening at the lower side in a lateral direction.

11. The manufacturing method of a semiconductor device of claim 10, wherein the opening is flat, and a polarization direction of the light of the wavelength λ is set perpendicular to a longitudinal direction of the opening.

12. The manufacturing method of a semiconductor device of claim 10, wherein the third layer is arranged at a middle position of the stacked body in the stack direction.

13. The manufacturing method of a semiconductor device of claim 10, wherein the opening includes a step at a position corresponding to the third layer.

14. The manufacturing method of a semiconductor device of claim 10, wherein,
where d1 denotes a thickness of the third layer, k1 denotes an extinction coefficient of the third layer relative to the wavelength λ, Ein denotes a light exposure amount of the resist with the light of the wavelength λ, and Eth denotes sensitivity of the resist,
a relationship of “Ein×exp(−4π·k1·d1/λ)<Eth” is satisfied.

15. The manufacturing method of a semiconductor device of claim 10, wherein the third layer is a polycrystalline silicon film, metal-containing film, or carbon film.

16. A manufacturing method of a semiconductor device, the method comprising:
forming a stacked body such that a first layer and a second layer, which are made of materials different from each other, are alternately stacked;
forming a cap layer on the stacked body, wherein the first layer or the second layer does not transmit light of a wavelength λ but the cap layer transmits the light of the wavelength λ;
forming an opening, which has a diameter or width smaller than the wavelength λ, through the stacked body, wherein the light having the wavelength λ is prevented from being transmitted by the first layer or the second layer;
forming a resist, which has sensitivity to the light of the wavelength λ, in the opening;
irradiating the resist formed in the opening with the light of the wavelength λ, and thereby forming a latent image in part of the resist in the opening at an upper side of the stacked body;
removing the part of the resist, in which the latent image is formed, and thereby exposing a sidewall of the opening at the upper side of the stacked body;
forming a protection film that covers the sidewall of the opening at the upper side of the stacked body;
removing part of the resist in the opening at a lower side of the stacked body, and thereby exposing a sidewall of the opening at the lower side of the stacked body; and
setting back the sidewall of the opening at the lower side of the stacked body in a lateral direction.

17. The manufacturing method of a semiconductor device of claim 16, wherein the opening is flat, and a polarization direction of the light of the wavelength λ is set perpendicular to a longitudinal direction of the opening.

18. The manufacturing method of a semiconductor device of claim 16, wherein,
where d1 denotes a thickness of the first layer or the second layer, which does not transmit the light of the wavelength λ, k1 denotes an extinction coefficient of the first layer or the second layer relative to the wavelength λ, Ein denotes a light exposure amount of the resist with the light of the wavelength λ, and Eth denotes sensitivity of the resist,
a relationship of “Ein×exp(−4π·k1·d1/λ)<Eth” is satisfied.

19. The manufacturing method of a semiconductor device of claim 16, wherein the first layer is a silicon layer doped with an impurity, the second layer is an interlayer insulating film, and the first layer is used as a word line of a memory cell.

20. The manufacturing method of a semiconductor device of claim 19, wherein the opening includes a memory hole configured to penetrate the word line, and a slit configured to divide the word line in accordance with a page unit.
